(19) United States
(12) Patent Application Publication
(10) Pub. No.: US 2020/0194637 A1
(43) Pub. Date: Jun. 18, 2020

(54) LIGHT EMITTING DIODE AND METHOD OF MANUFACTURING LIGHT EMITTING DIODE

(71) Applicant: SAMSUNG ELECTRONICS CO., LTD., Suwon-si (KR)

(72) Inventors: Eunhye KIM, Suwon-si (KR); Doyoung Kwag, Suwon-si (KR); Sangmoo Park, Suwon-si (KR); Minsub Oh, Seoul (KR); Yoonsuk Lee, Suwon-si (KR)

(73) Assignee: SAMSUNG ELECTRONICS CO., LTD., Suwon-si (KR)

(21) Appl. No.: 16/715,563

(22) Filed: Dec. 16, 2019

(30) Foreign Application Priority Data
Dec. 18, 2018 (KR) 10-2018-0164567

(51) Int. Cl. H01L 33/56

(52) U.S. Cl. CPC H01L 33/56; H01L 2933/005

(57) ABSTRACT

A light emitting diode is provided. The light emitting diode includes a substrate; a light emitting structure, and a protective layer. The light emitting structure is disposed on the substrate, and includes a first semiconductor layer, an active layer, and a second semiconductor layer. The protective layer is formed on the light emitting structure, and has a Young's modulus smaller than that of the light emitting structure.

### CROSS-REFERENCE TO RELATED APPLICATION(S)

This application is based on and claims priority under 35 U.S.C. § 119 to Korean Patent Application No. 10-2018-0164567, filed on Dec. 18, 2018, in the Korean Intellectual Property Office, the disclosure of which is incorporated by reference herein in its entirety.

### BACKGROUND

### 1. Field

The disclosure relates to a light emitting diode and a method of manufacturing a light emitting diode, and more particularly, to a light emitting diode and a method of manufacturing a light emitting diode capable of effectively preventing the light emitting diode from being damaged by external forces that may occur in the process of transferring and bonding the light emitting diode.

### 2. Description of the Related Art

Semiconductor light emitting diodes (LEDs) are being widely used as light sources for various kinds of display devices in various electronic products such as televisions (TVs), mobile phones, personal computers (PCs), notebook PCs, and personal digital assistants (PDAs), as well as light sources for illumination devices.

In particular, micro LEDs having a size of 100 μm or less have recently been developed, and the micro LEDs are spotlighted as light emitting diodes of next-generation displays due to their faster response speed, lower power consumption, and higher luminance than conventional LEDs.

Among the micro LEDs, flip chip-type LEDs not only have a structure that is advantageous for making a single element small, light and highly integrated, but also are capable of improving light emitting efficiency and transfer process efficiency in manufacturing display devices. Thus, the flip chip-type LEDs are employed in the micro LED field.

However, the light emitting diode may be cracked or broken due to external forces (stress) applied to the light emitting diode in the process of transferring and bonding the light emitting diode to a target substrate. The cracked or broken light emitting diode may reduce product yield of a display panel on which the light emitting diode is mounted.

### SUMMARY

In accordance with an aspect of the disclosure, there is provided a light emitting diode comprising a substrate; a light emitting structure disposed on the substrate and including a first semiconductor layer, an active layer, and a second semiconductor layer; and a protective layer formed on the light emitting structure and having a Young's modulus smaller than that of the light emitting structure.

In accordance with another aspect of the disclosure, there is provided a method comprising forming a light emitting structure on a growth substrate, the light emitting structure including a first semiconductor layer, an active layer, and a second semiconductor layer; forming a first electrode and a second electrode spaced electrically apart from each other by etching the light emitting structure; attaching a buffer layer and a support substrate to the light emitting structure; separating the growth substrate from the light emitting structure to which the support substrate is attached; forming a protective layer on the light emitting structure from which the growth substrate is separated, the protective layer having a Young's modulus smaller than that of the light emitting structure; and removing a region of the protective layer and the buffer layer to form a light emitting diode.

In accordance with another aspect of the disclosure, there is provided a light emitting diode comprising a substrate; a light emitting structure disposed on the substrate and including a first semiconductor layer, an active layer, and a second semiconductor layer; and means for relieving stress on the light emitting structure and preventing a crack in the light emitting structure.

Additional aspects will be set forth in part in the description which follows and, in part, will be apparent from the description, or may be learned by practice of the presented embodiments

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 is a schematic cross-sectional view of a light emitting diode according to an embodiment;

FIG. 2A is a schematic cross-sectional view of a light emitting diode according to an embodiment;

FIG. 2B is a cross-sectional view illustrating a state in which a protective layer illustrated in FIG. 2A is deformed by an external force, according to an embodiment;

FIG. 3A is a schematic cross-sectional view of a light emitting diode according to an embodiment;

FIG. 3B is a cross-sectional view illustrating a state in which a protective layer illustrated in FIG. 3A is deformed by an external force, according to an embodiment;

FIG. 4A is a schematic cross-sectional view of a light emitting diode according to an embodiment;

FIG. 4B is a cross-sectional view illustrating a state in which a protective layer illustrated in FIG. 4A is deformed by an external force, according to an embodiment;

FIG. 5 is a flowchart illustrating a process of manufacturing a light emitting diode according to an embodiment;

FIGS. 6A to 6F are cross-sectional views illustrating a process of manufacturing a light emitting diode according to an embodiment; and

FIG. 7 is a view illustrating a light emitting diode including a separating layer according to an embodiment.

### DETAILED DESCRIPTION

Hereinafter, embodiments of a light emitting diode and a method of manufacturing a light emitting diode according to the disclosure will be described in detail with reference to the accompanying drawings.

Embodiments described below are exemplarily described to help understanding of the disclosure, and it is to be understood that various modifications of the disclosure may be implemented unlike the embodiments described herein. However, in describing the disclosure, if it is determined that the detailed description of relevant known functions or elements may obscure the gist of the disclosure, the detailed description and concrete illustration thereof will be omitted. Further, to help understanding of the disclosure, the accompanying drawings are not necessarily illustrated to scale but dimensions of some elements may be exaggerated.

As used herein, the terms “1st” or “first” and “2nd” or “second” may use corresponding components regardless of importance or order and are used to distinguish one component from another without limiting the components. In this specification, the phrase “at least one of A and B” includes “only one A”, “only one B”, and “both A and B”.

The terms used in the embodiments of the disclosure may be construed as commonly known to those skilled in the art unless otherwise defined.

Terms such as “on”, “under”, “front end”, “rear end”, “upper portion”, “lower portion”, “upper end”, and “lower end”, when used herein, are defined on the basis of the drawings, and the shape and the position of each element are not limited by the terms.

The display module according to an embodiment of the disclosure may be applied to an electronic product or an electronic device that requires a wearable device, a portable device, a handheld device, or various displays, in a single unit. The display module can also be applied to a small display device such as a monitor for a personal computer, a TV, etc. and a large display device such as a digital signage, an electronic display through a plurality of assembly arrangements.

Hereinafter, the disclosure will be described in detail with reference to the accompanying drawings.

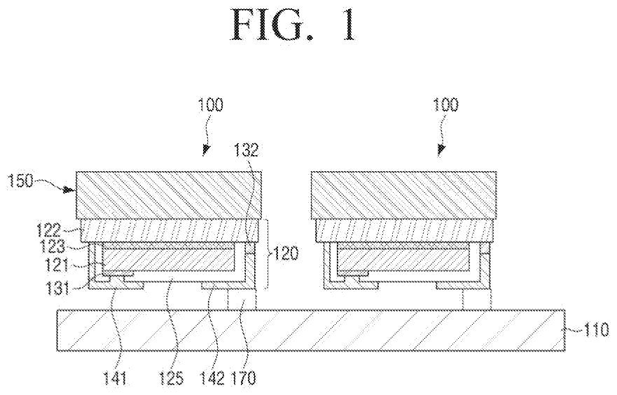

FIG. 1 is a schematic cross-sectional view of a light emitting diode according to an embodiment.

Referring to FIG. 1, a plurality of light emitting diodes 100 may be provided on a substrate 110 in a separated state from each other. The light emitting diodes 100 may each include, sequentially from the substrate 110, a first electrode pad 141 and a second electrode pad 142, a first electrode 131, a first semiconductor layer 121, an active layer 123, a second semiconductor layer 122, and a protective layer 150.

The substrate 110 may serve to support the light emitting diode 100 for a light emitting structure 120. In some embodiments, the light emitting structure 120 may include the first electrode pad 141 and the second electrode pad 142, the first electrode 131, the first semiconductor layer 121, the active layer 123, and the second semiconductor layer 122, as shown in FIG. 1.

The substrate 110 may include one or more of a sapphire substrate, a silicon substrate, a plastic substrate, and a plastic film. In addition, the substrate 110 may be formed by adhering a substrate of flexible material to the light emitting structure 120 and then attaching a substrate of rigid material thereto. The substrate of flexible material may prevent an excessive deformation and a crack in the light emitting structure 120, and the substrate of rigid material may firmly support the light emitting structure 120 and facilitate handling in the manufacturing process.

The light emitting diode 100 including the light emitting structure 120 and the protective layer 150 may be disposed on the substrate 110. In the light emitting diode 100, the light emitting structure 120 may be provided, and the protective layer 150 may be formed on the light emitting structure 120.

In the light emitting structure 120, the first semiconductor layer 121, the active layer 123, and the second semiconductor layer 122 may be stacked sequentially from the substrate 110.

The first semiconductor layer 121 may have a composition and a material that vary depending on a composition and a material of the active layer 123 formed thereon.

In addition, the first semiconductor layer 121 may have n-type conductivity. The first semiconductor layer 121 may be formed as a layer doped with an n-type dopant. The n-type dopant may be, for example, Si, Ge, Sn, Se, Te, or the like.

The second semiconductor layer 122 may be formed on the first semiconductor layer 121. The second semiconductor layer 122 is formed of the same base material as the first semiconductor layer 121 with a different dopant, and has complementary conductivity to the first semiconductor layer 121.

Thus, the second semiconductor layer 122 may have p-type conductivity. The second semiconductor layer 122 may be formed as a layer doped with a p-type dopant. The p-type dopant may be, for example, Zn, Mg, Co, Ni, Cu, Fe, C, or the like.

The first semiconductor layer 121 may be a layer providing electrons, and the second semiconductor layer 122 may be a layer providing holes.

The active layer 123 may be formed between the first semiconductor layer 121 and the second semiconductor layer 122. The first semiconductor layer 121, the active layer 123, and the second semiconductor layer 122 may be sequentially disposed in a vertical direction.

The active layer 123 is a layer where the electrons from the first semiconductor layer 121 are recombined with the holes from the second semiconductor layer 122 to output light having a predetermined wavelength, and the active layer 123 may have a single-quantum well structure or a multi-quantum well (MQW) structure by alternately stacking a well layer and a barrier layer. The active layer 123 may have a multi-quantum well (MQW) structure.

The light emitting structure 120 may include the first electrode pad 141 and the second electrode pad 142 electrically connected to a target substrate (not shown), which will be described later. The first and second electrode pads 141 and 142 may be provided as patterned metal.

The first electrode pad 141 and the second electrode pad 142 may form a flip chip structure.

The first electrode pad 141 may be electrically connected to the first semiconductor layer 121, and the second electrode pad 142 may be electrically connected to the second semiconductor layer 122.

The first electrode pad 141 may be formed on the bottom of the first semiconductor layer 121 by connecting a conductive material to the first electrode 131 formed on the first semiconductor layer 121. The second electrode pad 142 may be formed on the bottom of the first semiconductor layer 121 by connecting a conductive material to the second electrode 132 formed on the second semiconductor layer 122.

The first and second electrode pads 141 and 142 may be formed in a lower portion of the light emitting structure 120. Specifically, the first electrode pad 141 and the second electrode pad 142 may be disposed under the first semiconductor layer 121 and may be disposed adjacent to an upper portion of the substrate 110. The first electrode pad 141 and the second electrode pad 142 may be disposed on the same plane.

The light emitting diode 100 may be formed in a flip chip type by forming the first and second electrode pads 141 and 142 on the same plane on the bottom of the first semiconductor layer 121.

The flip chip-type light emitting diode 100 is advantageous in making the diode small, light and highly integrated. In addition, the light emitting diode 100 has a structure that the electrodes do not restrict a light emitting area in manufacturing a display device, thereby improving light emission efficiency, and the light emitting diode 100 does not use an intermediate medium such as a wire to be coupled to the target substrate, thereby improving transfer process efficiency.

The light emitting diode 100 may also be applied to a display device such as a monitor for a personal computer, a TV and digital signage, an electronic display through a plurality of assembly arrangement.

When the light emitting diode 100 that is flip-chip bonded in the above-described structure is mounted on the target substrate, which will be described later, and power is applied to the light emitting diode 100, in the active layer 123 the electrons and the holes are combined with each other to provide light.

In addition, in some embodiments, the light emitting structure 120 may further include a reflective layer 125 formed under the first semiconductor layer 121. In other embodiments, the reflective layer 125 may be omitted. The reflective layer 125 may reflect light provided from the active layer 123 toward the second semiconductor layer 122.

The reflective layer 125 may be made of a metal having a high reflectance to reflect light. For example, the reflective layer 125 may be made of a metal such as aluminum (Al), silver (Ag), nickel (Ni), or the like.

Some of the light provided from the active layer 123 is emitted to the outside through the second semiconductor layer 122, and the remaining light is reflected by the reflective layer 125 formed under the first semiconductor layer 121 and then emitted to the outside through the second semiconductor layer 122.

The light emitting diode 100 is in the flip chip structure, and the light from the active layer 123 is emitted to the outside through the second semiconductor layer 122 either directly or after being reflected, thereby increasing light efficiency.

The protective layer 150 may be included on the light emitting structure 120. Specifically, the protective layer 150 may be disposed on the second semiconductor layer 122.

The protective layer 150 may absorb an external force applied to an upper portion of the light emitting diode 100 to relieve a stress of the light emitting structure 120, thereby preventing a crack in the light emitting structure 120.

The protective layer 150 may be stretched by the stress applied to an upper portion of the light emitting structure 120. The protective layer 150 may relieve the stress applied to the light emitting structure 120 by being deformed in shape.

The protective layer 150 may have a low Young's modulus to protect the light emitting structure 120 from the external force. Specifically, the protective layer 150 may have a Young's modulus smaller than that of the light emitting structure 120.

The protective layer 150 may be greatly deformed by the external force applied to the upper portion of the light emitting diode 100, and thus, the stress of the light emitting structure 120 may be minimized.

The protective layer 150 may include a flexible material. When an external force is applied to the protective layer 150 itself, the protective layer 150 including a flexible polymer material may spread along an upper surface of the light emitting structure 120 due to the external force.

The protective layer 150 may include an elastic polymer (elastic rubber) and may have a stretchable property. The elastic polymer of the protective layer 150 according to an embodiment may include at least one of a silicone-based polymer, polyurethane, a polyurethane acrylate, an acrylate polymer, or an acrylate terpolymer. The silicone-based polymer may include, for example, at least one of polydimethylsiloxane, polyphenylmethylsiloxane, or hexamethyldisiloxane. Here, the polydimethylsiloxane may be abbreviated to “PDMS”, the polyurethane may be abbreviated to “PU”, and the polyurethane acrylate may be abbreviated to “PUA”. Specific materials of the protective layer 150 suggested herein are exemplary, and other elastic polymers may be used. The protective layer 150 may have stretchable a property on the basis of the elastic polymer.

The protective layer 150 may be disposed on an upper surface of the light emitting diode 100, which is a light emitting surface. Accordingly, the protective layer 150 may be formed of a transparent material to allow light provided from the light emitting diode 100 to penetrate therethrough.

In addition, the protective layer 150 may include an adhesive material. In some embodiments, the uppermost surface of the protective layer 150 may include the adhesive material.

In some other embodiments, the lowermost surface of the protective layer 150, which is brought into contact with the upper surface of the light emitting structure 120 to attach the protective layer 150 to the light emitting structure 120, may include the adhesive material. In yet some other embodiments, both the uppermost surface and the lowermost surface of the protective layer 150 may both include an adhesive material.

In order to transfer the light emitting diode 100 from the substrate 110 to the target substrate, the uppermost surface of the protective layer 150 may include the adhesive material.

A separating layer 170 may be disposed between the substrate 110 and the light emitting structure 120.

The separating layer 170 may connect the substrate 110 and the light emitting structure 120 to each other so that the light emitting structure 120 may be supported by the substrate 110.

When the light emitting diode 100 is separated from the substrate 110 to be mounted on the target substrate, the separating layer 170 facilitates separation of the light emitting diode 100 from the substrate 110.

The light emitting diode 100 on the substrate 110 may be physically separated from the substrate 110. At this time, the separating layer 170 may be disconnected or removed by applying an external force for separating the light emitting diode 100, thereby releasing connection between the substrate 110 and the light emitting diode 100.

The light emitting diode 100 may be easily separated from the substrate 110 by forming on the substrate 110 the separating layer 170 that is easily removable by the external force. In addition, the separating layer 170 may protect the light emitting diode 100 in the process of separating the light emitting diode 100 from the substrate 110.

The external force may be applied to the light emitting diode 100 in the process of separating the light emitting diode 100 from the substrate 110. The protective layer 150 may be disposed on the light emitting structure 120 to protect the light emitting structure 120 from the external force applied to the light emitting diode 100 to separate the light emitting diode 100 from the substrate 110.

The protective layer 150 may relieve the stress applied to the light emitting structure 120 while being deformed by the external force applied to the light emitting diode 100. Specifically, the protective layer 150 may be stretched along the upper surface of the light emitting structure 120 by an external force applied to an upper portion of the protective layer 150.

The protective layer 150 relieving the stress applied to the light emitting structure 120 may prevent a damage and a crack in the light emitting structure 120 during separation from the substrate 110.

Hereinafter, various structures of the protective layer 150 will be described.

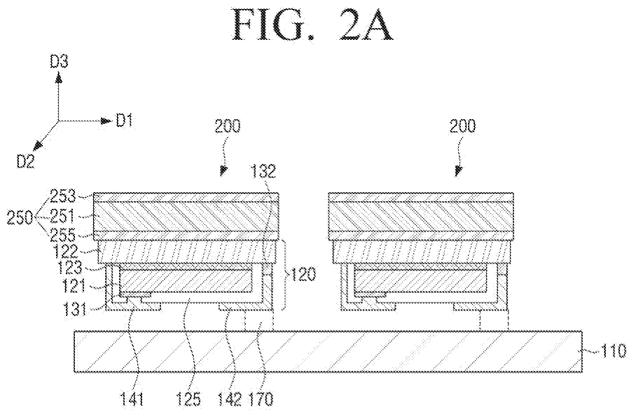

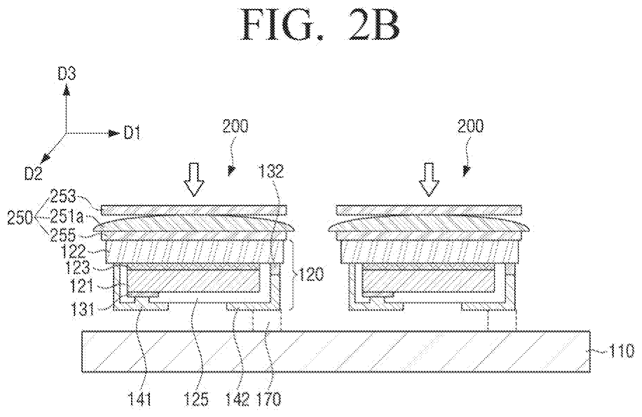

FIG. 2A is a schematic cross-sectional view of a light emitting diode according to an embodiment, and FIG. 2B is a cross-sectional view illustrating a state in which a protective layer illustrated in FIG. 2A is deformed by an external force, according to an embodiment.

Referring to FIG. 2A, the light emitting diode 200 has almost the same configuration as the light emitting diode 100 described with reference to FIG. 1, while being different only in that the protective layer 250 is formed in a multilayer structure. Concerning the light emitting diode 200, the detailed description of its configuration identically overlapping with that of the light emitting diode 100 described with reference to FIG. 1 will be omitted, and the different structure of the protective layer 250 will be mainly explained.

The protective layer 250 may be formed in a multilayer structure.

The protective layer 250 may include a deformation layer 251, and an upper support layer 253 and a lower support layer 255 supporting upper and lower portions of the deformation layer 251, respectively.

The deformation layer 251 may have a low Young's modulus to protect the light emitting structure 120 from an external force. Specifically, the deformation layer 251 may have a Young's modulus smaller than that of the light emitting structure 120.

The deformation layer 251 may absorb an external force applied to an upper portion of the light emitting diode 200 to relieve a stress on the light emitting structure 120 to prevent a crack in the light emitting structure 120.

Due to the stress applied to the upper portion of the light emitting diode 200, the deformation layer 251 may be stretched in a direction perpendicular to the stress. The deformation layer 251 may relieve the stress applied to the light emitting structure 120 by being deformed in shape.

The deformation layer 251 may be interposed between the upper and lower support layers 253 and 255. Each of the upper support layer 253 and the lower support layer 255 may have a Young's modulus greater than that of the deformation layer 251. In some embodiments, the Young's modulus of the upper and lower support layers 253 and 255 may be the same. In some other embodiments, the Young's modulus of the upper and lower support layers 253 and 255 may be different from each other. In some embodiments, the Young's modulus of the upper support layer 253 and the lower support layer 255 may be similar to or the same as that of the light emitting structure 120.

The upper support layer 253 and the lower support layer 255 may support the deformation layer 251 having a low Young's modulus.

In some embodiments, the upper support layer 253 and the lower support layer 255 may be longer than the deformation layer 251. For example, in some embodiments, the upper support layer 253 and the lower support layer 255 may be longer than the deformation layer 251 in a direction D1 shown in FIG. 2A. In other embodiments, the upper support layer 253 and the lower support layer 255 may be longer than the deformation layer 251 in a direction D2, or in both the directions D1 and D2. Accordingly, the deformation layer 251 may be supported by the upper support layer 253 and the lower support layer 255 even when stretched.

Referring to FIG. 2B, a deformation layer 251a of the protective layer 250 may be deformed by an external force applied to the upper portion of the light emitting diode 200 such that the protective layer 250 has shape that is stretched in a direction perpendicular to the external force. As shown in FIG. 2B, the external force may be in a direction −D3 as shown by the arrow.

The external force may be applied to the upper portion of the light emitting diode 200 in the process of separating the light emitting diode 200 from the substrate 110 to mount the light emitting diode 200 onto the target substrate (not shown), i.e., a substrate different from the substrate 110).

The light emitting diode 200 disposed on the substrate 110 may be transferred to the target substrate by a transfer device (not shown). The transfer device may be connected to the upper portion of the light emitting diode 200. An attractive force between the light emitting diode 200 and the transfer device may be greater than that between the light emitting diode 200 and the substrate 110 when adhering the transfer device to the light emitting diode 200 so that the light emitting diode 200 may be separated from the substrate 110. In this case, the separating layer 170 connecting the substrate 110 and the light emitting diode 200 may be disconnected to release the connection between the substrate 110 and the light emitting diode 200.

In addition, a pressure may be applied to the upper portion of the light emitting diode 200 in the direction −D3 shown in FIG. 2B in the process of bonding to the target substrate the light emitting diode 200 that is transferred to the target substrate.

An external force may be applied to the upper portion of the light emitting diode 200 in the process of transferring and bonding the light emitting diode 200. The external force applied to the upper portion of the light emitting diode 200 may deform the protective layer 250 to be stretched in the direction perpendicular to the external force.

Specifically, the deformation layer 251a disposed between the upper support layer 253 and the lower support layer 255 may be stretched by the external force in a direction parallel to the substrate 110.

The deformation layer 251a stretched in the direction perpendicular to the external force may be in an arc shape with the center portion being convex. The deformation layer 251a may be stretched outwardly while getting thinner at both side ends thereof such that both side ends thereof are spaced apart from the upper support layer 253, as shown in FIG. 2B. In some embodiments, a portion of the deformation layer 251a that stretched by the external force may be beyond the upper support layer 253 and the lower support layer 255.

As the deformation layer 251a is stretched, a thickness of the protective layer 250 may be reduced at both side ends thereof, as shown in FIG. 2B.

The stretched deformation layer 251 may relieve the external force transmitted to the light emitting structure 120, thereby preventing the light emitting structure 120 from being finely broken or cracked by the external force.

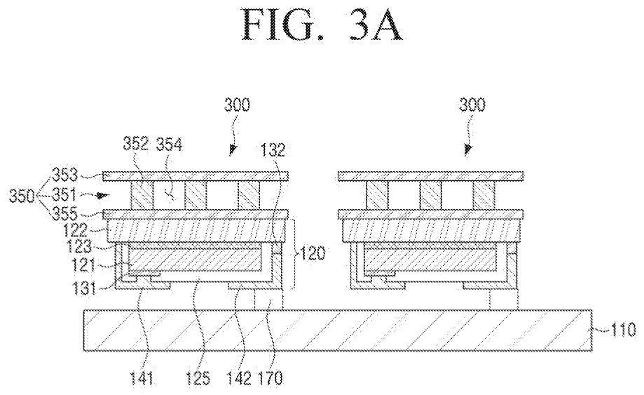

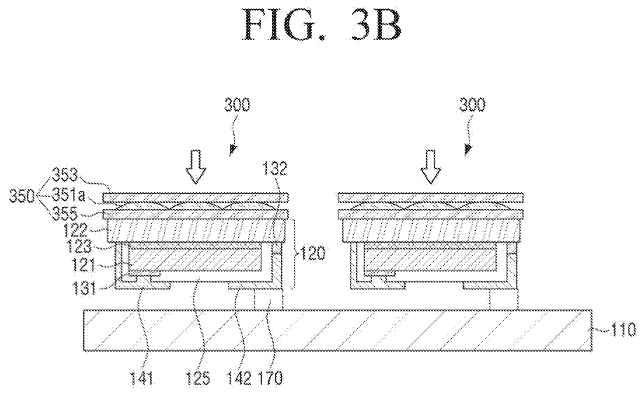

FIG. 3A is a schematic cross-sectional view of a light emitting diode according to an embodiment, and FIG. 3B is a cross-sectional view illustrating a state in which a protective layer illustrated in FIG. 3A is deformed by an external force.

Referring to FIG. 3A, the light emitting diode 300 may have almost the same configuration as the light emitting diode 200 described with reference to FIG. 2A, while being different only in that a deformation layer 351 of the protective layer 350 includes deformation portions 352 spaced apart from each other. Concerning the light emitting diode 300, the detailed description of its configuration identically overlapping with that of the light emitting diode 200 described with reference to FIG. 2A will be omitted, and the different structure of the deformation layer 351 will be mainly explained.

The protective layer 350 may be formed in a multilayer structure, including a deformation layer 351, an upper support layer 353 and a lower support layer 355 supporting the upper and lower portions of the deformation layer 351, respectively.

The deformation layer 351 may have a low Young's modulus to protect the light emitting structure 120 from an external force. Specifically, the deformation layer 351 may have a Young's modulus smaller than that of the light emitting structure 120.

The deformation layer 351 may be spaced apart at a predetermined interval between an upper support layer 353 and a lower support layer 355.

For example, the deformation layer 351 may include a plurality of band-shaped deformation portions 352 formed of a material having a low Young's modulus and a space portion 354 formed between the plurality of deformation portions 352. The plurality of deformation portions 352 may be spaced apart from each other at predetermined intervals between the upper support layer 353 and the lower support layer 355. The space portion 354 may be formed between each two adjacent deformation portions 352.

It is illustrated that the deformation portions 352 are spaced apart from each other at the same distance, but embodiments are not limited thereto. The deformation portions 352 may be spaced apart from each other at irregular intervals.

Referring to FIG. 3B, a deformation layer 351a may be deformed by an external force applied to an upper portion of the light emitting diode 300 such that the deformation layer 351a has a shape as to be stretched in a direction perpendicular to the external force.

Each deformation portion 352 may be stretched by the external force in a direction parallel to the substrate 110. Each deformation portion 352 may be stretched to be widened toward the space portions 354 formed on the sides of the deformation portion 352, as illustrated in FIG. 2B.

Each stretched deformation portion 352 may be in an arc shape, with the center portion being convex. Each deformation portion 352 may be stretched outwardly so that its height is decreased and both of its side ends become thinner towards the space portions 354.

As the deformation portions 352 are stretched, the space portions 354 may be filled with a material having a low Young's modulus.

As a result, a thickness of the protective layer 350 may be reduced, and the deformation layer 351a may be stretched beyond the upper support layer 353 and the lower support layer 355.

The stretched deformation layer 351 may relieve the external force transmitted to the light emitting structure 120, thereby preventing the light emitting structure 120 from being finely broken or cracked by the external force.

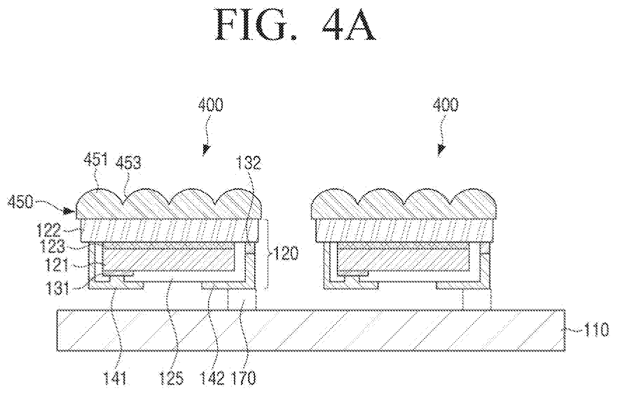

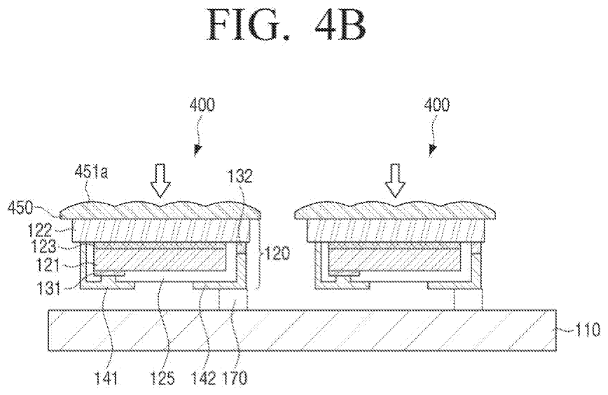

FIG. 4A is a schematic cross-sectional view of a light emitting diode according to an embodiment, and FIG. 4B is a cross-sectional view illustrating a state in which a protective layer illustrated in FIG. 4A is deformed by an external force, according to an embodiment.

Referring to FIG. 4A, the light emitting diode 400 has almost the same configuration as the light emitting diode 100 described with reference to FIG. 1, while being different only in that the protective layer 450 has a corrugated structure. Concerning the light emitting diode 400, the detailed description of its configuration identically overlapping with that of the light emitting diode 100 described with reference to FIG. 1 will be omitted, and the different structure of the protective layer 450 will be mainly explained.

As illustrated in FIG. 4A, the protective layer 450 may have a corrugated structure.

The corrugated structure may have a low Young's modulus to protect the light emitting structure 120 from an external force. Specifically, the corrugated structure may have a Young's modulus smaller than that of the light emitting structure 120.

The corrugated structure may include corrugations 451 having a generally regular period, and an upper surface of the corrugated structure may be corrugated.

For example, the corrugated structure may include one or more corrugations 451 projecting convexly from the upper portion of the light emitting structure 120. The corrugations 451 may be uniformly formed at regular intervals. It is illustrated in FIG. 4A that the corrugated structure includes uniform corrugations 451, but embodiments are not limited thereto. The corrugations 451 in the corrugated structure may be formed in an irregular manner.

The corrugations 451 in the corrugated structure may have a diameter varying from several micrometers to several tens of micrometers.

At least one curve portion 453 may be formed between adjacent corrugations 451 among the plurality of corrugations 451. The curve portion 453 may be filled with the corrugations 451 deformed by an external force in the process where the protective layer 450 is deformed, which will be described later.

Referring to FIG. 4B, the corrugated structure may be deformed by an external force applied to an upper portion of the light emitting diode 400 such that the corrugated structure has a shape that is stretched in a direction perpendicular to the external force. Specifically, the corrugated structure may be deformed such that corrugations 451a are stretched out.

The corrugations 451a may be stretched toward the curve portions 453. The stretched corrugations 451 may fill the curve portions 453 so that the upper surface of the corrugated structure is deformed to be generally flat.

As a result, a thickness of the protective layer 450 may be reduced as much as the flattened degree of the projecting corrugations 451a, and the corrugated structure may be stretched beyond the light emitting structure 120, as illustrated in FIG. 4B.

The stretched corrugations 451a may relieve the external force transmitted to the light emitting structure 120, thereby preventing the light emitting structure 120 from being finely broken or cracked by the external force.

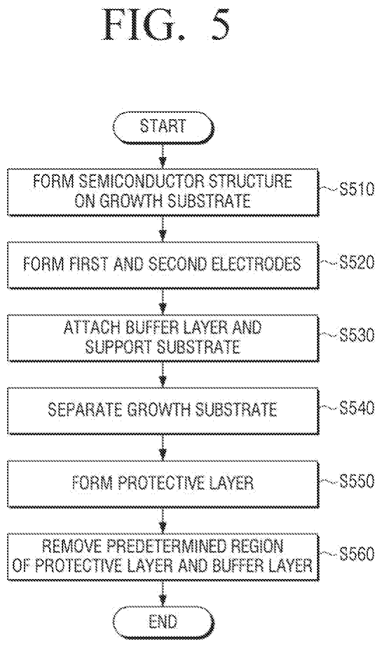

FIG. 5 is a flowchart illustrating a process of manufacturing a light emitting diode according to an embodiment.

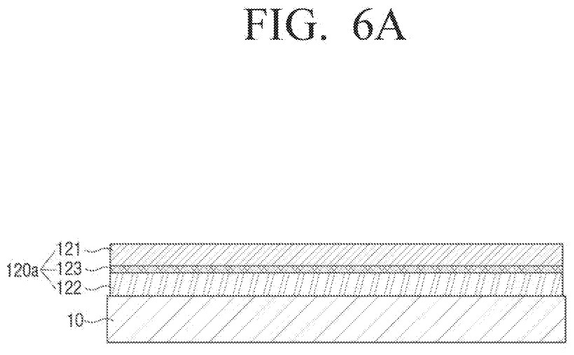

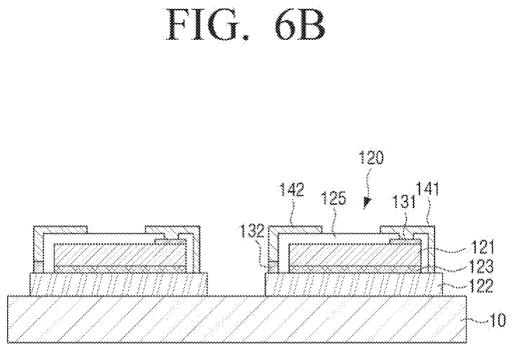

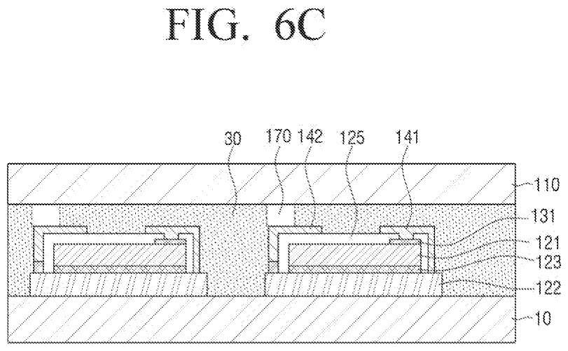

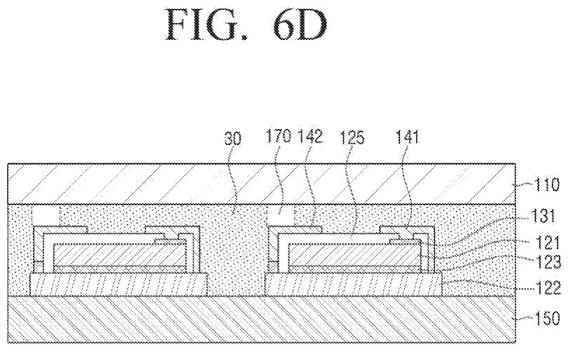

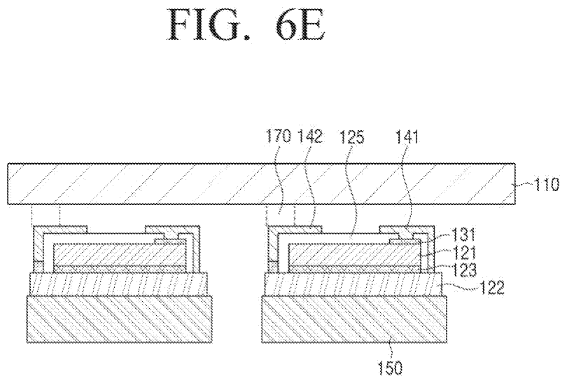

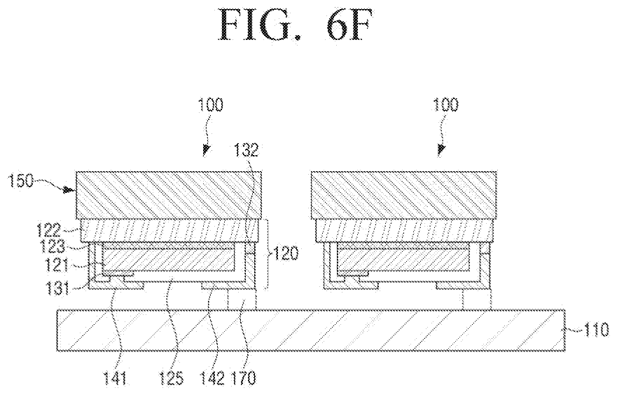

Referring to FIG. 5, a method of manufacturing a light emitting diode 100 may include: forming a light emitting structure 120 on a growth substrate 10 (S510); forming first and second electrode pads 141 and 142 on the light emitting structure 120 (S520); attaching a buffer layer and a support substrate 110 to the light emitting structure 120 (S530); separating the growth substrate 10 from the light emitting structure (120) to which the support substrate 110 is attached (S540); forming a protective layer (150) on the light emitting structure (120) from which the growth substrate (10) is separated (S550); and removing a predetermined region of the protective layer 150 and the buffer layer 30 (S560). Hereinafter, each step of the manufacturing method will be described in detail with reference to FIGS. 6A to 6F.

FIGS. 6A to 6F are cross-sectional views illustrating a process of manufacturing a light emitting diode according to an embodiment.

FIG. 6A is a cross-sectional view illustrating a process of forming the light emitting structure 120 on the growth substrate 10. For example, the light emitting structure 120 may be grown on the growth substrate 10.

Referring to FIG. 6A, the light emitting structure 120 may be grown on the growth substrate 10, the light emitting structure 120 including a first semiconductor layer 121, an active layer 123, and a second semiconductor layer 122 sequentially stacked.

FIG. 6B is a cross-sectional view illustrating a process of forming electrodes of a light emitting diode according to an embodiment.

Referring to FIG. 6B, the light emitting structure 120 is etched such that the second semiconductor layer 122 is partially exposed, and then a second electrode 132 is formed on the exposed portion of the second semiconductor layer 122. Likewise, the light emitting structure 120 is also etched such that the first semiconductor layer 121 is partially exposed, and then a first electrode 131 is formed on the exposed portion of the first semiconductor layer 121. Thereafter, the first and second electrode pads 141 and 142 are formed.

FIG. 6C is a cross-sectional view illustrating a process of forming a separating layer 170 on the light emitting structure 120 and attaching the buffer layer 30 and the support substrate 110 thereto according to an embodiment.

Referring to FIG. 6C, the separating layer 170 may be formed on the light emitting structure 120 to connect the support substrate 110 and the light emitting structure 120 to each other. The buffer layer 30 may be filled to adhere to the light emitting structure 120 formed with the separating layer 170, and then the support substrate 110 may be attached thereto.

FIG. 6D is a view illustrating a process of removing the growth substrate 10 and attaching the protective layer 150 according to an embodiment.

Referring to FIG. 6D, the growth substrate 10 may be separated from the light emitting structure 120 to improve light extraction efficiency, because the growth substrate 10 absorbs a light emission spectrum.

In some embodiments, the light emitting structure 120 may be fixed to the support substrate 110 while the growth substrate 10 is removed.

The protective layer 150 may be attached to an upper end of the light emitting structure 120 from which the growth substrate 10 is removed. The protective layer 150 may have a Young's modulus smaller than that of the light emitting structure 120.

The protective layer 150 may be formed by coating a flexible material on the light emitting structure 120.

In some embodiments, the protective layer 150 may have a deformation layer 251, 351 having a Young's modulus smaller than that of the light emitting structure 120. The protective layer 250, 350 may further include support layers 253, 353 and 255, 355 supporting upper and lower portions of the deformation layer 251, 351, respectively.

In some embodiments, the protective layer 150 may include corrugations 451 (see FIG. 4A) on the upper surface of the protective layer 150. The protective layer 150 may include a flexible polymer material as described above. Accordingly, the corrugations 451 may form a corrugated structure as illustrated in the embodiment of FIG. 4A, when a tension is removed after being applied to the protective layer 150 itself The corrugations 451 in the corrugated structure of the protective layer 150 may be formed through mechanical and physical deformation using a mold having a shape corresponding to the corrugated shape.

In some embodiments, the corrugated structure of the protective layer 150 may be formed by performing a plasma treatment or a partial chemical etching on the upper surface of the protective layer 150 as well as the mechanical and physical deformation method.

FIG. 6E is a cross-sectional view illustrating a process of removing the predetermined region of the protective layer 150 and the buffer layer 30 according to an embodiment.

Referring to FIG. 6E, the protective layer 150 may be etched to correspond to one light emitting structure 120. One separate light emitting diode 100 may be formed by removing the predetermined region of the protective layer 150 and the buffer layer 30.

As the predetermined region of the protective layer 150 is removed, the protective layer 150 may be disposed at a position corresponding to the upper surface of the light emitting structure 120. Accordingly, the protective layer 150 may protect the light emitting structure 120 against the external force applied to the upper portion of the light emitting diode 100.

FIG. 6F is a cross-sectional view illustrating a light emitting diode 100 according to an embodiment.

Referring to FIG. 6F, after forming a plurality of independent light emitting diodes 100, the method may further include separating the light emitting diodes 100 from the support substrate 110 to mount each light emitting diode 100 on a target substrate.

In the process of separating the light emitting diode 100 from the support substrate 110, the protective layer 150 may be deformed in shape to minimally transmit to the light emitting structure 120 the external force applied to the upper portion of the light emitting diode 100.

The protective layer 150 may absorb the external force (i.e., in the −D3 direction) by being stretched on the light emitting structure 120 along a plane (i.e., in the D1 and D2 directions) parallel to the support substrate 110. As a result, it is possible to prevent a crack that may occur in the process of transferring the light emitting diode 100.

In addition, a pressure may be applied to the upper portion of the light emitting diode 100 in the process of bonding the transferred light emitting diode 100 to the target substrate. In this case, the protective layer 150 may be deformed in shape, thereby absorbing the external force applied to the upper portion of the light emitting diode 100 and thus relieving the stress of the light emitting structure 120. As a result, it is possible to prevent a crack in the light emitting structure 120.

The protective layer 150 may be removed in a state after the light emitting diode 100 is mounted on the target substrate. Light efficiency may be increased when the protective layer 150 is removed, because the protective layer 150 is formed on the light emitting surface of the light emitting diode 100. Even if the protective layer 150 is not removed, propagation of light outputted from the light emitting surface is not interrupted because the protective layer 150 is formed of a transparent material.

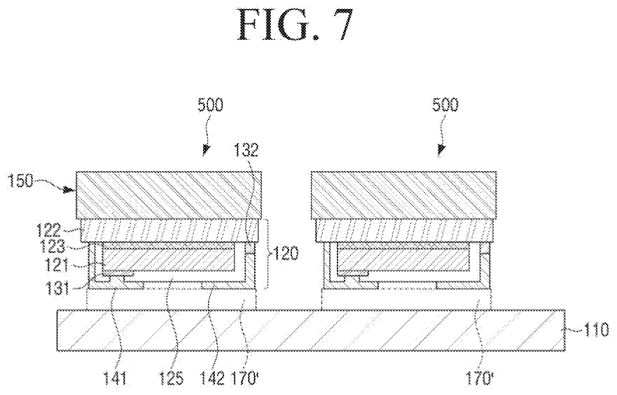

FIG. 7 is a view illustrating a light emitting diode including a separating layer according to an embodiment.

Referring to FIG. 7, the light emitting diode 500 according to an embodiment has almost the same configuration as the light emitting diode 100 described with reference to FIG. 1, while being different only in that the light emitting diode 500 includes a separating layer 170′ formed of an adhesive material. Concerning the light emitting diode 500, the detailed description of its configuration identically overlapping with that of the light emitting diode 100 described with reference to FIG. 1 will be omitted, and the different structure of the separating layer 170′ will be mainly explained.

The separating layer 170′ may be disposed between the substrate 110 and the light emitting structure 120.

The separating layer 170′ may connect the substrate 110 and the light emitting structure 120 to each other so that the light emitting structure 120 may be supported by the substrate 110.

When the light emitting diode 500 is separated from the substrate 110 to be mounted on the target substrate, the separating layer 170′ facilitates separation of the light emitting diode 500 from the substrate 110.

The separating layer 170′ may be formed of an adhesive material.

The light emitting diode 500 on the substrate 110 may be physically separated from the substrate 110. Specifically, the light emitting diode 500 may be separated from the substrate 110 through a separating structure (not shown) that is adhered by an adhesive to the upper portion of the light emitting diode 500.

An adhesion between the light emitting diode 500 and the separating structure may be greater than an adhesion between the separating layer 170′ and the substrate 110. The light emitting diode 500 may be separated from the substrate 110 due to a difference of the adhesion between the separating structure and the light emitting diode 500 from the adhesion between the separating layer 170′ and the light emitting diode 500, the former adhesion being greater than the latter.

As the adhesion between the separating structure and the light emitting diode 500 is greater than that between the substrate 110 and the light emitting diode 500, the connection between the substrate 110 and the light emitting diode 500 may be released by the separating structure.

The light emitting diode 500 may easily be separated from the substrate 110 by forming the separating layer 170′ having a weaker adhesion than the separating structure on the substrate 110. In addition, the separating layer 170′ may protect the light emitting diode 500 in the process of separating the substrate 110.

In the process of separating the light emitting diode 500 from the substrate 110, an external force may be applied to the light emitting diode 500. In addition, an external force may also be applied to the light emitting diode 500 in the process of mounting the separated light emitting diode 500 on a device substrate. The protective layer 150 may be disposed on the light emitting structure 120 to protect the light emitting structure 120 from the external forces applied to the light emitting diode 500.

The protective layer 150 may relieve stress applied to the light emitting structure 120 while being deformed in shape by the external forces applied to the light emitting diode 500. Specifically, the protective layer 150 may be stretched along the upper surface of the light emitting structure 120 by the external force applied to the upper portion of the protective layer 150.

The protective layer 150 relieving the stress applied to the light emitting structure 120 may prevent damages and cracks in the light emitting structure 120.

The protective layer 150 included in the light emitting diode 500 may be formed in various ways as described above with reference to FIGS. 2A, 3A, and 4A.

The disclosure has been described in an exemplary manner above. The terms used herein are only for description and should not be interpreted as limiting. The disclosure may be modified and changed in various ways based on the description provided above. Accordingly, the disclosure may be freely implemented within the scope of the claims, unless otherwise described.

What is claimed is:

1. A light emitting diode comprising:
a substrate;
a light emitting structure disposed on the substrate and including a first semiconductor layer, an active layer, and a second semiconductor layer; and
a protective layer formed on the light emitting structure and having a Young's modulus smaller than that of the light emitting structure.

2. The light emitting diode as claimed in claim 1, wherein the protective layer is formed of a flexible material.

3. The light emitting diode as claimed in claim 1, wherein the protective layer includes a corrugated structure on an upper surface thereof.

4. The light emitting diode as claimed in claim 3, wherein the corrugated structure of the protective layer includes a plurality of corrugations projecting convexly from an upper portion of the light emitting structure, and a curve portion formed between each two adjacent corrugations among the plurality of corrugations.

5. The light emitting diode as claimed in claim 1, wherein the protective layer is formed in a multilayer structure, and includes a deformation layer having a Young's modulus smaller than that of the light emitting structure.

6. The light emitting diode as claimed in claim 5, wherein the protective layer further includes:
an upper support layer configured to support an upper portion of the deformation layer; and
a lower support layer configured to support a lower portion of the deformation layer.

7. The light emitting diode as claimed in claim 6, wherein each of the upper support layer and the lower support layer have a Young's modulus greater than that of the deformation layer.

8. The light emitting diode as claimed in claim 6, wherein the deformation layer includes a plurality of deformation portions spaced apart from each other at predetermined intervals.

9. The light emitting diode as claimed in claim 1, wherein the light emitting structure includes a first electrode and a second electrode spaced electrically apart from each other, and
the protective layer is formed on a side of the light emitting structure opposite to a side on which the first electrode and the second electrode are formed.

10. The light emitting diode as claimed in claim 1, wherein the protective layer is formed of a transparent material.

11. The light emitting diode as claimed in claim 1, wherein an uppermost surface of the protective layer includes an adhesive material.

12. A method comprising:
forming a light emitting structure on a growth substrate, the light emitting structure including a first semiconductor layer, an active layer, and a second semiconductor layer;
forming a first electrode and a second electrode spaced electrically apart from each other by etching the light emitting structure;
attaching a buffer layer and a support substrate to the light emitting structure;
separating the growth substrate from the light emitting structure to which the support substrate is attached;
forming a protective layer on the light emitting structure from which the growth substrate is separated, the protective layer having a Young's modulus smaller than that of the light emitting structure; and
removing a region of the protective layer and the buffer layer to form a light emitting diode.

13. The method as claimed in claim 12, wherein the protective layer is coated on the light emitting structure.

14. The method as claimed in claim 12, wherein in the forming of the protective layer, a lower support layer, a deformation layer, and an upper support layer are sequentially stacked, the deformation layer having a Young's modulus smaller than that of the light emitting structure.

15. The method as claimed in claim 12, wherein in the forming of the protective layer, a plurality of corrugations are formed on an upper surface of the protective layer.

16. The method as claimed in claim 15, wherein the plurality of corrugations are formed through a mechanical molding, a plasma treatment, or a partial chemical etching.

17. The method as claimed in claim 14, further comprising, after the removing of the region of the protective layer and the buffer layer to form the light emitting diode:
transferring the light emitting diode onto a target substrate; and
removing the protective layer of the light emitting diode transferred onto the target substrate.

18. A light emitting diode comprising:
a substrate;
a light emitting structure disposed on the substrate and including a first semiconductor layer, an active layer, and a second semiconductor layer; and
means for relieving stress on the light emitting structure and preventing a crack in the light emitting structure.

19. The light emitting diode as claimed in claim 18, wherein the means is a deformation means that deforms to relieve the stress and prevent the crack.

20. The light emitting diode as claimed in claim 19, wherein the deformation means deforms in response to an external force applied to the light emitting diode in a process of transferring the light emitting diode from the substrate and bonding the light emitting diode to a target substrate different from the substrate.
